(19) United States
(12) Patent Application Publication
(10) Pub. No.: US 2026/0362977 A1
(43) Pub. Date: Nov. 12, 2026

(54) THERMOELECTRIC CONVERSION DEVICE

(71) Applicant: TOHOKU UNIVERSITY, Sendai-shi, Miyagi (JP)

(72) Inventors: Atsushi TSUKAZAKI, Sendai-shi (JP); Kohei FUJIWARA, Sendai-shi (JP); Junichi SHIOGAI, Sendai-shi (JP)

(21) Appl. No.: 19/120,735

(22) PCT Filed: Oct. 12, 2022
(86) PCT No.: PCT/JP2022/038027

§ 371 Date: Apr. 11, 2025

(51) Int. Cl. H10N 10/854; C22C 30/04; C22C 38/00; H10N 10/17

(52) U.S. Cl. CPC H10N 10/854; C22C 30/04; C22C 38/008; H10N 10/17

(57) ABSTRACT

A thermoelectric conversion device (100) of the invention includes a substrate (101), a thermoelectric conversion film (102) formed on one surface (101a) of the substrate, first temperature applying unit (105) configured to apply a temperature to the thermoelectric conversion film (102) on a side of the substrate (101), and a second temperature applying unit (106) configured to apply a temperature to the thermoelectric conversion film (102) on a side opposite to the substrate (101), the temperature being different from the temperature on the side of the substrate. The thermoelectric conversion film (102), has an amorphous structure made of a composition containing Feₓ and Sn₁₋ₓ (0.4≤x≤09).

The present application is based on PCT/JP2022/038027 filed on Oct. 12, 2022, and the contents thereof are incorporated herein.

### TECHNICAL FIELD

The present invention relates to a thermoelectric conversion device.

### BACKGROUND ART

A thermoelectric conversion technique has attracted attention as an essential technique for energy recycling, energy conservation, and an advanced IoT technique. The thermoelectric conversion technique is used to generate a thermoelectromotive force in various applications such as power generation by collecting exhaust heat from factories and automobiles, monitoring with a heat flow sensor, and power generation using a temperature difference between a body temperature and outside air.

The thermoelectromotive force generated by thermoelectric conversion is generally based on the Seebeck effect. When performing thermoelectric conversion using the Seebeck effect, a semiconductor material having a high Seebeck coefficient is widely used. However, since a direction in which a thermoelectromotive force is generated is the same as (parallel to) a direction in which a temperature difference occurs, there are many restrictions on an element design, such as a three-dimensional element structure being required for increasing thermoelectromotive force. A semiconductor material that generates a high thermoelectromotive force is often composed of a rare and toxic element. The semiconductor material is known to be mechanically brittle, and an improvement is required from the viewpoint of reduction in environmental load and flexibility.

In recent years, a thermoelectric material that generates a thermoelectromotive force due to an anomalous Nernst effect has attracted attention (Patent Literature 1 and the like). A difference is that the thermoelectromotive force due to the Seebeck effect is generated in parallel to a direction of a temperature gradient, whereas the thermoelectromotive force due to the anomalous Nernst effect is generated in a direction perpendicular to both a direction of a temperature gradient and a magnetization direction of a sample. For example, when there is a temperature gradient in a Z-axis direction of a thermoelectric material having magnetization oriented in a Y-axis direction, a thermoelectromotive force is generated in an X-axis direction. Therefore, by devising a shape, size, disposition, and the like of the thermoelectric material, a magnitude of the thermoelectromotive force can be adjusted, and an element structure different from a related-art thermoelectric conversion device based on the Seebeck effect can be utilized.

As a substance exhibiting excellent thermoelectric properties due to the anomalous Nernst effect, a crystalline bulk sample and a crystalline thin film sample have been reported so far, and a high-temperature treatment is generally required in a manufacturing process thereof (for example, Non Patent Literature 1). Therefore, it is difficult to form a thin film on a flexible organic polymer substrate or a general-purpose glass substrate at room temperature. Some substances are difficult to form thinly while maintaining a crystal structure.

In recent years, a flexible thermoelectric conversion element obtained by dispersing Fe, Ni, Cr, Al, or the like in a polymer has been reported (for example, Patent Literature 2), but the thermoelectric conversion element of such a form is a mixture of different materials such as a polymer and metal particles, and therefore has a problem with thermal stability and is unsuitable for practical applications.

In order to use the thermoelectric conversion element in combination with other elements as a compact thermoelectric module or the like, a thin-film thermoelectric conversion material made of a single component that can be mounted on a substrate as an element is required.

### CITATION LIST

### Patent Literature

Patent Literature 1: JP2020-098860A
Patent Literature 2: JP2021-128999A

### Non Patent Literature

Non Patent Literature 1: Taishi Chen et al., “Large anomalous Nernst effect and nodal plane in an iron-based kagome ferromagnet”, Sci. Adv. 8, eabk1480, 14 Jan. 2022

### SUMMARY OF INVENTION

### Technical Problem

The invention has been made in view of the above circumstances, and an object thereof is to provide a thermoelectric conversion device that has excellent thermoelectric properties and flexibility, has a small environmental load, and can be manufactured at room temperature.

### Solution to Problem

In order to solve the above problems, the invention employs the following method.

A thermoelectric conversion device according to one aspect of the invention includes: a substrate; a thermoelectric conversion film formed on one surface of the substrate; a first temperature applying unit configured to apply a temperature to the thermoelectric conversion film on a substrate side; and a second temperature applying unit configured to apply a temperature to the thermoelectric conversion film on a side opposite to the substrate side, the temperature being different from the temperature on the substrate side. The thermoelectric conversion film has an amorphous structure made of a composition containing Fe and Sn.

### Advantageous Effects of Invention

The invention can provide a thermoelectric conversion device that has excellent thermoelectric properties and flexibility, has a small environmental load, and can be manufactured at room temperature.

### BRIEF DESCRIPTION OF DRAWINGS

FIG. 1 is a perspective view of a thermoelectric conversion device according to an embodiment of the invention.

FIG. 2 is a perspective view of a thermoelectric conversion device according to Application Example 1 of the embodiment.

FIG. 3 is a perspective view of a thermoelectric conversion device according to Application Example 2 of the embodiment.

FIG. 4 illustrates measurement results of an X-ray diffraction pattern of a thermoelectric conversion film represented by a composition formula FeₓSn₁₋ₓ that is formed on a glass substrate, in which (a) to (f) illustrates results when x is 0.42, 0.52, 0.60, 0.65, 0.74, 0.84, and 0.87, respectively.

FIG. 5 is a graph illustrating a relationship between a surface-perpendicular applied magnetic field and anomalous Hall resistivity ρ_{yx} of the thermoelectric conversion film represented by the composition formula FeₓSn₁₋ₓ that is formed on the glass substrate, in which results are illustrated for x=0.42 to 0.87.

FIG. 6 is a graph illustrating a relationship between the surface-perpendicular applied magnetic field and an anomalous Nernst coefficient S_{xy} of the thermoelectric conversion film represented by the composition formula FeₓSn₁₋ₓ that is formed on the glass substrate, in which results are illustrated for x=0.42 to 0.87.

FIG. 7 is a graph illustrating a relationship between the anomalous Nernst coefficient S_{xy} and an Fe composition ratio x in thermoelectric conversion films each represented by composition formulae FeₓSn₁₋ₓ and Feₓ (Al_{y}Sn_{1-y})₁₋ₓ) that are formed on the glass substrate, in which in the drawing, black circles represent results for FeₓSn₁₋ₓ when x=0.42 to 0.87, and a white circle represents a result for Al-doped Fe_{0.77}(Al_{0.48}Sn_{0.52})_{0.23}.

FIG. 8 is a graph illustrating a relationship between a transverse thermal conductivity α_{xy} and the Fe composition ratio x in the thermoelectric conversion films each represented by the composition formulae FeₓSn₁₋ₓ and Feₓ (Al_{y}Sn_{1-y})₁₋ₓ) that are formed on the glass substrate, in which black circles represent results for FeₓSn₁₋ₓ when x=0.42 to 0.87, and a white circle represents a result for Al-doped Fe_{0.77}(Al_{0.48}Sn_{0.52})_{0.23}.

FIG. 9 is a graph illustrating a relationship between a Hall angle σ_{xy}/σₓₓ and the Fe composition ratio x in the thermoelectric conversion film represented by the composition formula FeₓSn₁₋ₓ that is formed on the glass substrate, in which black circles represent results for FeₓSn₁₋ₓ when x=0.42 to 0.87, and a white circle represents a result for Al-doped Fe_{0.77} (Al_{0.48}Sn_{0.52})_{0.23}.

FIG. 10 is a measurement result of an X-ray diffraction pattern of the thermoelectric conversion film represented by the composition formula Fe_{0.77}(Al_{0.48}Sn_{0.52})_{0.23} that is formed on the glass substrate.

FIG. 11 is a graph illustrating a relationship between a surface-perpendicular applied magnetic field and anomalous Hall resistivity ρ_{yx} of a thermoelectric conversion film represented by the composition formula Feₓ (Al_{y}Sn_{1-y})₁₋ₓ (x=0.74, y=0.48) that is formed on the glass substrate.

FIG. 12 is a graph illustrating a relationship between a surface-perpendicular applied magnetic field and an anomalous Nernst coefficient S_{xy} of a thermoelectric conversion film represented by the composition formula Feₓ (Al_{y}Sn_{1-y})₁₋ₓ (x=0.77, y=0.48) that is formed on the glass substrate.

FIG. 13 is a graph illustrating a relationship between a surface-perpendicular applied magnetic field and anomalous Hall resistivity ρ_{yx} of a thermoelectric conversion film represented by the composition formula FeₓSn₁₋ₓ (x=0.44 to 0.87) that is formed on an Al₂O₃ substrate.

FIG. 14 is a graph illustrating a relationship between a surface-perpendicular applied magnetic field and an anomalous Nernst coefficient S_{xy} of the thermoelectric conversion film represented by the composition formula FeₓSn₁₋ₓ (x=0.44 to 0.87) that is formed on the Al₂O₃ substrate.

FIG. 15 is a graph illustrating a relationship between the anomalous Nernst coefficient S_{xy} and an Fe composition ratio x in the thermoelectric conversion film represented by the composition formula FeₓSn₁₋ₓ (x=0.44 to 0.87) that is formed on the Al₂O₃ substrate.

FIG. 16 is a graph illustrating a relationship between a transverse thermal conductivity α_{xy} and the Fe composition ratio x in the thermoelectric conversion film represented by the composition formula FeₓSn₁₋ₓ (x=0.44 to 0.87) that is formed on the Al₂O₃ substrate.

FIG. 17 is a graph illustrating a relationship between a Hall angle σ_{xy}/σₓₓ and the Fe composition ratio x in the thermoelectric conversion film represented by the composition formula FeₓSn₁₋ₓ (x=0.44 to 0.87) that is formed on the Al₂O₃ substrate.

FIG. 18 illustrates a cross-sectional transmission electron microscope image of a thermoelectric conversion film represented by a composition formula Fe_{0.60}Sn_{0.40} that is formed on the Al₂O₃ substrate.

FIG. 19 illustrates a cross-sectional transmission electron microscope image of a thermoelectric conversion film represented by a composition formula Fe_{0.491}Sn_{0.278} Ta_{0.231} that is formed on the Al₂O₃ substrate.

### DESCRIPTION OF EMBODIMENTS

Hereinafter, a thermoelectric conversion device according to an embodiment to which the invention is applied will be described in detail with reference to the drawings. The drawings used in the following description may show feature portions in an enlarged manner for convenience in order to make features easier to be understood, and dimensional ratios of components may not be the same as in reality. A material, a dimension, and the like exemplified in the following description are merely examples, and the invention is not limited thereto, and can be appropriately modified and implemented without departing from the gist of the invention.

### (Thermoelectric Conversion Device)

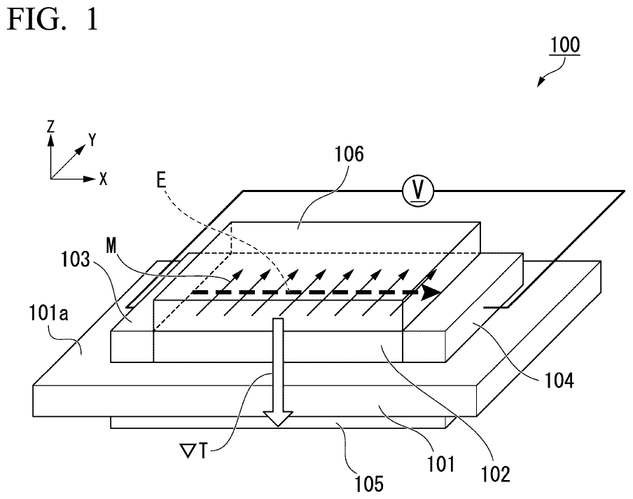

FIG. 1 is a perspective view of a thermoelectric conversion device 100 according to an embodiment of the invention. The thermoelectric conversion device 100 mainly includes a substrate 101, a thermoelectric conversion film 102, a first electrode 103, a second electrode 104, a first temperature applying unit 105, and a second temperature applying unit 106. Here, a Z axis perpendicular to one surface (main surface) 101a of the substrate and an X axis and a Y axis orthogonal to each other in a plane parallel to the one surface 101a are defined.

A shape of the substrate 101 is not limited, and is preferably a flat plate shape. A material of the substrate 101 may be any material that can form the thermoelectric conversion film 102, and is determined according to a material of the thermoelectric conversion film 102. In the present embodiment, since the thermoelectric conversion film 102 made of a metal material is used, for example, Al₂O₃, SiO₂, MgO, SrTiO₃, glass, or a polymer can be used as the material of the substrate. For the substrate, in order to obtain a high-quality amorphous film, it is suitable to use a non-crystalline substrate such as glass, which does not have an effect of promoting thin film crystallization through the matching of crystal orientation or lattice constant. When flexibility is required for the substrate 101, it is preferable to use, for example, an organic material, a polymer film, a resin film, or the like that has a low thermal conductivity, insulating properties, and flexibility.

The thermoelectric conversion film 102 is formed on the one surface 101a of the substrate, and is made of an Fe—Sn composition containing Fe (iron) and Sn (tin). The composition is represented by a composition formula FeₓSn₁₋ₓ, where 0.4≤x≤0.9. The larger the Fe composition ratio x, the higher the magnetization. In particular, 0.8≤x≤0.9 is preferred. A film of the Fe—Sn composition can be formed on any substrate at room temperature (about 25 °C to 30 °C), and is inexpensive and excellent in environmental harmony.

The thermoelectric conversion film 102 has magnetic order due to Fe, and therefore exhibits the anomalous Nernst effect when magnetized in a predetermined direction and subjected to a temperature gradient. The anomalous Nernst effect is a phenomenon in which an electric field (an electromotive force) is generated in a direction of a cross product of a temperature gradient and magnetization. As will be described later as an example, by combining Fe and Sn, a huge anomalous Nernst effect is exhibited, and a thermoelectromotive force coefficient (an anomalous Nernst coefficient) exceeding 1 μV/K can be obtained.

Here, an example is illustrated in which a magnetic field is applied by a magnetic field application method (not illustrated) in a direction parallel to one surface of the substrate to magnetize the thermoelectric conversion film 102, but a magnetization direction may be freely set depending on the application, and for example, the thermoelectric conversion film 102 may be magnetized in a direction perpendicular to one surface of the substrate. Examples of a method for controlling the magnetization direction include a method in which a magnetic field generating unit such as a magnet is disposed circumferentially to apply a magnetic field in a predetermined direction to a portion to be magnetized, and a method in which a portion to be magnetized is irradiated with light with a polarized state corresponding to the magnetization direction.

The composition may further contain an element A selected from a transition element such as Ta (tantalum), W (tungsten), Pt (platinum), Mo (molybdenum), and Mn (manganese), which have a potential to enhance an electromotive force due to the anomalous Nernst effect through modulation of magnetic interaction and spin-orbit interaction. The composition in this case is represented by a composition formula Fe_{x-y}Sn_{1-x-z}A_{y+z}, where 0.4≤x≤0.9, 0.05≤y≤0.6, and 0.05≤z≤0.4. The composition may further contain an element B selected from a magnetic element such as a typical element such as In (indium), Al (aluminum), Ge (germanium), Si (silicon), and Ga (gallium), which have a potential to enhance an electromotive force due to the anomalous Nernst effect through modulation of carrier density and spin-orbit interaction. The composition in this case is represented by a composition formula Fe_{x-y}Sn_{1-x-z}B_{y+z}, where 0.4≤x≤0.9, 0.05≤x≤0.6, and 0.05≤z≤0.4.

A shape of the thermoelectric conversion film 102 is determined according to the application. In the present embodiment, the thermoelectric conversion film 102 having a shape extending in one direction (an X direction) is exemplified. A thickness of the thermoelectric conversion film 102 is not limited, and is preferably 4 nm or more and 1000 nm or less. A Seebeck coefficient and an anomalous Nernst coefficient do not depend on the thickness of the thermoelectric conversion film 102.

The thermoelectric conversion film 102 has a mostly amorphous (non-crystalline, glass) structure, is a soft magnetic material, has flexibility, and has high mechanical strength (tensile strength, toughness, hardness, and the like) and high corrosion resistance. The fact that the thermoelectric conversion film 102 has an amorphous structure can be indirectly confirmed by, for example, performing X-ray diffraction measurement. When a sharp peak due to Bragg reflection is not observed in an X-ray diffraction pattern obtained by the measurement, that is, when a peak value associated with the Bragg reflection is equal to noise (a signal-to-noise ratio (S/N ratio) is 30 or less), it can be determined that the thermoelectric conversion film 102 has an amorphous structure. The amorphous structure is preferably contained in a volume ratio of 50% or more of the thermoelectric conversion film 102.

By using the flexible substrate 101, the flexibility of the thermoelectric c conversion device 100 can be increased. The flexibility of the thermoelectric conversion device 100 can be confirmed using, for example, a jig having a curved surface. That is, when the thermoelectric conversion device 100 is attached to a curved surface portion of the jig in a bent state and a state where no crack occurs in the substrate 101 and the thermoelectric conversion film can be maintained, it can be determined that the thermoelectric conversion device 100 has flexibility.

The thermoelectric conversion film 102 may have a nearly completely amorphous structure (90% or more of a total volume), or may have microcrystals in which a plurality of portions (nanocrystal portions) having a nanocrystalline structure are distributed in an amorphous structure. A volume ratio of the nanocrystalline structure in the thermoelectric conversion film 102 is not particularly limited as long as the amorphous structure is contained at 50% or more in the thermoelectric conversion film 102.

The first electrode 103 and the second electrode 104 are each made of a conductive material such as an indium, a paste of gold, or silver, a conductive wire of a metal such as gold or aluminum, or a deposited film of gold or platinum. The first electrode 103 is connected to a portion (a left end in FIG. 1) of the thermoelectric conversion film 102, and the second electrode 104 is connected to another portion (a right end in FIG. 1) of the thermoelectric conversion film 102. A thermoelectromotive force generated between the first electrode 103 and the second electrode 104 is output.

The first electrode 103 and the second electrode 104 may not be provided in a case where electric power is directly extracted.

The first temperature applying unit 105 and the second temperature applying unit 106 are a unit (a commercially available temperature controller or the like) that applies a temperature to a predetermined portion of the thermoelectric conversion film 102. The first temperature applying unit 105 is disposed so as to apply a temperature to the thermoelectric conversion film 102 on a substrate 101 side (a lower side in FIG. 1), and is connected to the thermoelectric conversion film 102 with the substrate 101 therebetween. The second temperature applying unit 106 is disposed so as to apply a temperature to the thermoelectric conversion film 102 on a side (an upper side in FIG. 1) opposite to the substrate 101, and is directly connected to the thermoelectric conversion film 102. Here, a case where a temperature on a first temperature applying unit 105 side is set relatively high, a temperature on a second temperature applying unit 106 side is set relatively low, and a temperature gradient ∇T is generated from the second temperature applying unit 106 side toward the first temperature applying unit 105 side is exemplified.

The first temperature applying unit 105 and the second temperature applying unit 106 are not limited to a device such as a heat source such as a heater that is driven by applying a current to a resistor to accurately adjust a temperature, a heat bath, or a refrigerant, and may also be waste heat generated by friction or industry, or heat from a surrounding environment such as a human body temperature or an air temperature. Any unit may be used as long as it generates a significant temperature difference between the first temperature applying unit 105 and the second temperature applying unit 106.

In the present embodiment, since a direction of the temperature gradient ∇T is a Z-axis direction and a direction of magnetization M is a Y-axis direction, a thermoelectromotive force due to the anomalous Nernst effect is generated in an X-axis direction parallel to the one surface 101a of the substrate. Therefore, by forming the thermoelectric conversion film 102 long in the X-axis direction, the obtained thermoelectromotive force can be increased.

### (Method for Manufacturing Thermoelectric Conversion Device)

The thermoelectric conversion device 100 of the present embodiment can be manufactured mainly through the following steps.

### [Formation of Thermoelectric Conversion Film]

The thermoelectric conversion film 102 is formed on the one surface 101a of the substrate using a known film deposition method such as a sputtering method. As an example of a film deposition condition, a substrate temperature can be hold at room temperature, an RF output can be set to 50 W, Ar gas pressure can be set to 0.5 Pa, and a target-to-substrate distance can be set to 100 mm by using an RF magnetron sputtering device and a mosaic target in which a 10 mm square Fe chip is disposed on a 2 inch diameter Sn disk. Under the film deposition condition, the thermoelectric conversion film 102 having an amorphous structure can be obtained. In a range in which crystallization does not occur, in order to adjust a deposition rate of a thin film or the like according to the application, the substrate temperature may be set to 0 °C or higher and 400 °C or lower, the RF output may be set to 5 W to 200 W, the Ar gas pressure may be set to 0.01 Pa to 10 Pa, and the target-to-substrate distance may be set to 50 mm to 200 mm.

Subsequently, the formed thermoelectric conversion film 102 is processed into a desired shape using a photolithography method or the like.

The processed thermoelectric conversion film 102 may be subjected to a heat treatment for 0 hours to 24 hours at a temperature of 0 °C or higher and 400 °C or higher at which crystallization does not occur. The thermoelectric conversion film 102 of the invention can be manufactured by a manufacturing method such as a vacuum deposition method, an electron beam deposition method, a molecular beam epitaxy method, a chemical vapor deposition method, electrodeposition, or electrodeposition.

### [Formation of Electrode]

The first electrode 103 and the second electrode 104 that are connected to the thermoelectric conversion film 102 are formed using a known film deposition method such as a sputtering method. The film deposition condition is the same as that for forming the thermoelectric conversion film.

Subsequently, the formed first electrode 103 and second electrode 104 are processed into a desired shape using a photolithography method or the like.

The processed first electrode 103 and second electrode 104 may be subjected to a heat treatment.

### [Disposition of Temperature Applying Unit]

The first temperature applying unit 105 (device) is disposed on a side opposite to the thermoelectric conversion film 102 when viewed from the substrate 101. The second temperature applying unit 106 (device) is disposed on a side opposite to the substrate 101 when viewed from the thermoelectric conversion film 102. Accordingly, the thermoelectric conversion device 100 of the present embodiment is obtained.

As described above, in the thermoelectric conversion device 100 of the present embodiment, the thermoelectric conversion film 102 is made of a composition combining Fe and Sn, and has excellent thermoelectric properties due to the anomalous Nernst effect. Further, since the thermoelectric conversion film 102 of the present embodiment has a mostly amorphous structure, has high flexibility, and can be formed on various substrates at room temperature, the thermoelectric conversion device 100 of the present embodiment can be used as a flexible device. The thermoelectric conversion film 102 of the present embodiment has a mostly amorphous structure, can be formed on any substrate at room temperature, and is inexpensive and excellent in environmental harmony. Fe and Sn forming the thermoelectric conversion film are a low-toxicity material, and therefore impose a smaller environmental load than when a semiconductor material such as bismuth and tellurium is used.

As in the present embodiment, when the temperature gradient in the Z-axis direction is applied to the thermoelectric conversion film 102 magnetized in the Y-axis direction, the thermoelectromotive force due to the anomalous Nernst effect is generated in the X-axis direction parallel to the one surface 101a of the substrate. Therefore, a magnitude of the generated thermoelectromotive force can be controlled by adjusting a size of the thermoelectric conversion film 102 in the X-axis direction.

FIG. 1 illustrates a case where a sign of an anomalous Nernst coefficient of the thermoelectric conversion film 102 is positive, the thermoelectric conversion film 102 is magnetized in a +direction of the Y axis (a +Y direction), and a thermoelectromotive force is generated in a +direction of the X axis (a +X direction). On the other hand, when the thermoelectric conversion film 102, whose sign of the anomalous Nernst coefficient is negative, is magnetized in a +direction of the Y axis (a +Y direction), a thermoelectromotive force is generated in a −direction of the X axis (a −X direction). The thermoelectric conversion device 100 of the present embodiment can be variously applied by combining such thermoelectric conversion films having anomalous Nernst coefficients with different signs.

The invention is based on a discovery that a thermoelectric conversion film containing Fe and Sn exhibits a significant anomalous Nernst effect even in an amorphous state. Previous studies have focused on a crystalline material to investigate the origin of the anomalous Nernst effect, but the origin has remained unknown.

While investigating the origin of the anomalous Nernst effect of thermoelectric conversion film containing Fe and Sn, the present inventor discovers that even a thermoelectric conversion film composed entirely of an amorphous material exhibits a significant anomalous Nernst effect.

Based on other analysis results and the like, the present inventors consider that the origin of this is that, in Fe and Sn, a kagome lattice, which is a basic structure of a Fe₃Sn crystal mentioned in Non Patent Literature 1, is maintained in a short-distance region of nearest neighbors even in an amorphous sample, and other analyses have provided results that support this. That is, the present inventors presume that, in Fe and Sn, a short-range order of the kagome lattice exists at a nearest-neighbor level, and the existence of the short-range order contributes to an electronic state, leading to manifestation of a large anomalous Nernst effect.

When the short-range order exists and the anomalous Nernst effect is generated, there is no need for crystallization, and there is more freedom in a method of doping another metal, and thus an inexpensive thermoelectric conversion element having an anomalous Nernst effect can be obtained.

### [Application Example of Specific Structure of Thermoelectric Conversion Device]

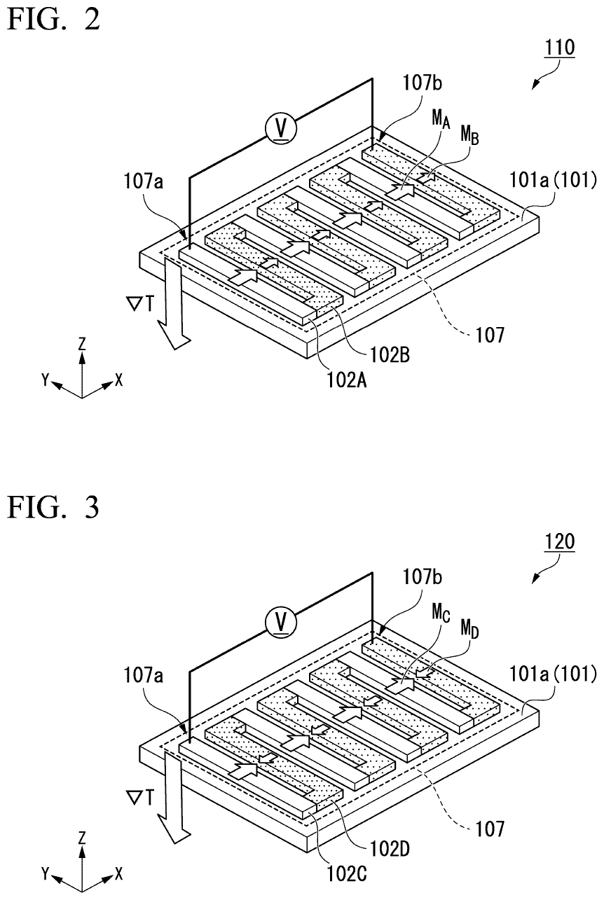

FIG. 2 is a perspective view of a thermoelectric conversion device 110 according to Application Example 1 of the present embodiment. In the thermoelectric conversion device 110, the thermoelectric conversion film 102 is formed by combining patterns of two magnetic materials having anomalous Nernst coefficients with different signs. Other configurations of the thermoelectric conversion device 110 are the same as those of the thermoelectric conversion device 100, and at least the thermoelectric conversion device 110 provides the same effects as the thermoelectric conversion device 100. Portions corresponding to those of the thermoelectric conversion device 100 are denoted by the same reference numerals. Here, illustration of the first temperature applying unit 105 and the second temperature applying unit 106 is omitted.

The thermoelectric conversion film 102 of Application Example 1 has a wavy pattern 107 on the one surface 101a of the substrate, and includes a plurality of first patterns (first magnetic materials) 102A extending substantially parallel to each other in the same direction (here, the Y-axis direction) and a second pattern 102B connecting adjacent first patterns 102A to each other. Adjacent first patterns 102A have anomalous Nernst coefficients with different signs. Here, one of the two adjacent first patterns 102A has an anomalous Nernst coefficient S_{XY+} with a positive sign and magnetization M_{A}, and the other one thereof has an anomalous Nernst coefficient S_{XY-} with a negative sign and magnetization M_{B}. A direction of the magnetization M_{A} and a direction of the magnetization M_{B} are the same.

In the first pattern 102A having an anomalous Nernst coefficient with a positive sign, a thermoelectromotive force is generated in a −direction of a Y axis (a −Y direction), which is a direction of a cross product of the temperature gradient ∇T and the magnetization M. On the other hand, in the first pattern 102A having an anomalous Nernst coefficient with a negative sign, a thermoelectromotive force is generated in a +direction of the Y axis (a +Y direction), which is a direction opposite to the cross product of the temperature gradient ∇T and the magnetization M.

Therefore, in the plurality of first patterns 102A arranged in an X-axis direction, a direction of the generated thermoelectromotive force alternately changes in an arrangement order. Therefore, all the first patterns 102A are connected in series via the second pattern 102B, and a current path from one end 107a to the other end 107b of the wavy pattern 107 is formed. The greater the number of first patterns 102A, the longer the current path that is formed, and therefore the greater the thermoelectromotive force that can be generated.

FIG. 1 illustrates a case where a sign of an anomalous Nernst coefficient of the thermoelectric conversion film 102 is positive, the thermoelectric conversion film 102 is magnetized in a +direction of the Y axis (a +Y direction), and the thermoelectromotive force is generated in a +direction of the X axis (a +X direction). On the other hand, when the thermoelectric conversion film 102 having an anomalous Nernst coefficient with the same sign is magnetized in a −direction of the Y axis (a −Y direction), a thermoelectromotive force is generated in a −direction of the X axis (a −X direction). The thermoelectric conversion device 100 of the present embodiment can be variously applied by combining such thermoelectric conversion films having different magnetization directions.

FIG. 3 is a perspective view of a thermoelectric conversion device 120 according to Application Example 2 of the present embodiment. In the thermoelectric conversion device 120, the thermoelectric conversion film 102 is formed by combining patterns of two magnetic materials having different magnetization directions. Other configurations of the thermoelectric conversion device 120 are the same as those of the thermoelectric conversion device 100, and at least the thermoelectric conversion device 120 provides the same effects as the thermoelectric conversion device 100. Portions corresponding to those of the thermoelectric conversion device 100 are denoted by the same reference numerals. Here, illustration of the first temperature applying unit 105 and the second temperature applying unit 106 is omitted.

The thermoelectric conversion film 102 of Application Example 2 has a wavy pattern 107 on the one surface 101a of the substrate, and includes a plurality of first patterns (first magnetic materials) 102C extending substantially in parallel in the same direction (here, a Y-axis direction) and a second pattern (a second magnetic material) 102D connecting adjacent first patterns 102C to each other. Adjacent first patterns 102C are magnetized in opposite directions. Here, one of the two adjacent first patterns 102C has magnetization M_{C} in a +direction of the X axis (a +X direction), and the other one thereof has magnetization M_{D} in a −direction of the X axis (a −X direction).

In the first pattern 102C magnetized in the +X direction, a thermoelectromotive force is generated in a −direction of the Y axis (a −Y direction), which is a direction of a cross product of the temperature gradient ∇T and the magnetization M_{C}. On the other hand, in the first pattern 102D magnetized in the −X direction, a thermoelectromotive force is generated in a +direction of the Y axis (a +Y direction), which is a direction opposite to a cross product of the temperature gradient ∇T and the magnetization M_{D}.

Therefore, in the plurality of first patterns 102C arranged in the X-axis direction, a direction of the generated thermoelectromotive force alternately changes in an arrangement order. Therefore, all the first patterns 102C are connected in series via the second pattern 102D, and a current path from the one end 107a to the other end 107b of the wavy pattern 107 is formed. The greater the number of first patterns 102C, the longer the current path that is formed, and therefore the greater the thermoelectromotive force that can be generated.

### EXAMPLE

Effects of the invention will be more clearly understood based on the following examples. The invention is not limited to the following examples, and can be appropriately modified without departing from the scope of the invention.

### Example 1-1: Thermoelectric Conversion Device of Invention Using Thermoelectric Conversion Film Composed Only of Amorphous Material

### [Composition Dependency]

A plurality of samples of the thermoelectric conversion device of the invention were manufactured, and thermoelectric properties thereof were measured. A glass substrate was used as a substrate. The reason why a glass substrate is used in the Example is that when a crystalline substrate is used, there is a possibility of partial crystallization (microcrystal formation) due to the influence of the substrate. As the thermoelectric conversion film, a thin film (thickness: 28 nm to 46 nm) made of a composition represented by a composition formula FeₓSn₁₋ₓ was used. By performing thin film growth by a sputtering method using an RF magnetron sputtering device (ES-250 manufactured by EIKO CORPORATION), a thermoelectric conversion film composed of almost 100% amorphous material was obtained. An amorphous structure was confirmed with an X-ray diffractometer (Smart Lab manufactured by Rigaku Corporation and Empyrean manufactured by Spectris Malvern Panalytical). When FeₓSn₁₋ₓ is crystallized, FeₓSn₁₋ₓ generally forms a kagome lattice crystal structure as described in Non Patent Literature 1, but in X-ray diffraction illustrated in (a) to (g) of FIG. 4, no sharp peak derived from these crystals was observed in thin films with x=0.42 to 0.87. A member made of indium was used as an electrode for detecting the anomalous Hall effect and the anomalous Nernst effect.

For seven samples in which an Fe composition ratio x was 0.42, 0.52, 0.60, 0.65, 0.74, 0.84, and 0.87, a magnetic field (a surface-perpendicular applied magnetic field) was applied in a thickness direction of the thermoelectric conversion film, and temperatures at one end side and the other end side in a direction orthogonal to the magnetic field were set to 300 K using the first temperature applying unit and the second temperature applying unit, respectively. Here, when a current was caused to flow from one end side (a side of the first temperature applying unit) to the other end side (a side of the second temperature applying unit) of the thermoelectric conversion film, a Hall voltage generated between the electrodes due to the anomalous Hall effect was measured.

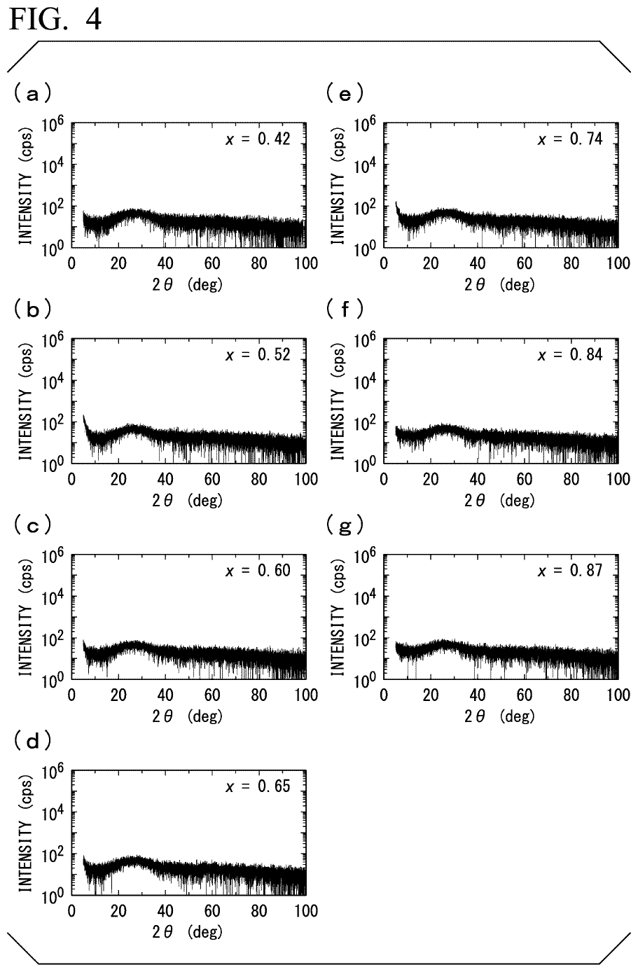

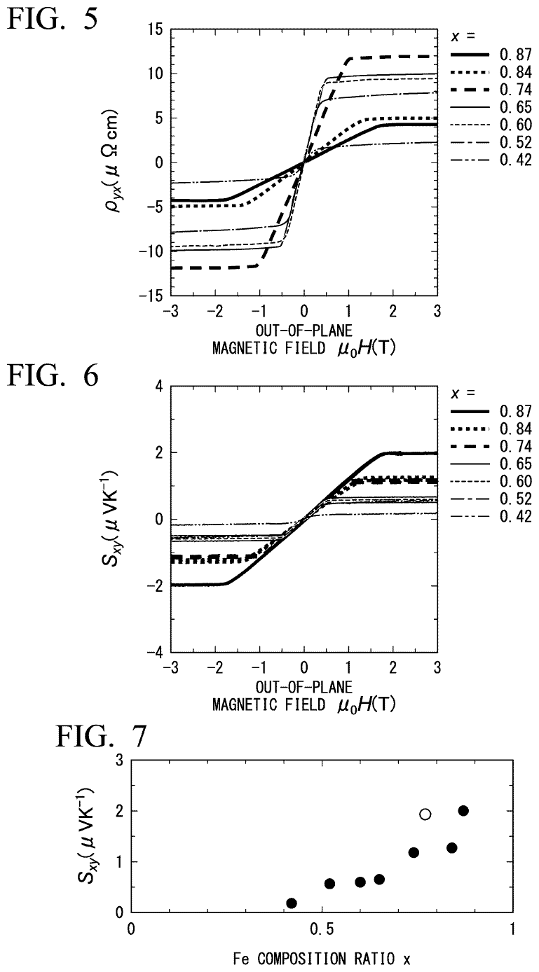

FIG. 5 is a graph illustrating a result of the measurement. A horizontal axis in the graph represents a surface-perpendicular applied magnetic field (T), and a vertical axis in the graph represents Hall resistivity pyx [μΩ·cm]. From this graph, it can be seen that a change in magnetization direction caused by application of a magnetic field is reflected in the Hall resistivity.

In the seven samples, the magnetic field was applied in the thickness (out-of-plane) direction of the thermoelectric conversion film, and the temperature on one end side was maintained at about 302 K by the first temperature applying unit and the temperature on the other end side was adjusted to about 307 K by the second temperature applying unit in the direction orthogonal to the magnetic field without applying a current. As the first temperature applying unit, a sample holder of a refrigerator (VersaLab manufactured by Quantum Design) was used as a heat bath, and as the second temperature applying unit, heating by applying an electric current to a resistor was used. A temperature difference generated in the sample was calculated by measuring a resistance of a Pt/Ti bilayer film formed on the same substrate as the thermoelectric conversion film and obtaining temperatures at a plurality of points on the substrate with reference to a resistance-temperature dependence curve acquired in advance. At this time, a thermoelectromotive force V_{xy} generated between the electrodes due to the anomalous Nernst effect was measured.

FIG. 6 is a graph illustrating a result of the measurement. A horizontal axis in the graph represents the surface-perpendicular applied magnetic field (T), and a vertical axis in the graph represents an anomalous Nernst coefficient S_{xy} [μV·K⁻¹]. A relationship between the anomalous Nernst coefficient S_{xy} and the thermoelectromotive force V_{xy} is defined by the following formula (1) using an inter-electrode distance W used for measurement and a temperature gradient (∇T)ₓ in an X-axis direction.

S_{xy}=V_{xy}/W/(∇T)ₓ (1)

It can be seen from the graph in FIG. 6 that a change in magnetization direction caused by application of the magnetic field is reflected in the anomalous Nernst coefficient. It can be seen that, depending on a composition ratio of Fe and Sn, a large anomalous Nernst coefficient occurs at a certain composition ratio.

For all the samples manufactured as Example 1-1, the anomalous Hall effect was measured by the above-described procedure, and a Hall angle σ_{xy}/σₓₓ was calculated based on the Hall resistivity pyx and electrical resistivity ρₓₓ. The hole conductivity σ_{xy} and the electrical conductivity σₓₓ are defined by the following formulae (2 and 3).

σ_{xy}=ρ_{yx}/(ρₓₓ2+ρ_{yx}²) (2)

σₓₓ=ρₓₓ/(ρₓₓ2+ρ_{yx}²) (3)
ρ_{yx}: Hall resistivity
ρₓₓ: electrical resistivity

For all the samples manufactured as Example 1-1, the anomalous Nernst effect was measured by the above-described procedure, and the anomalous Nernst coefficient S_{xy} and a transverse thermal conductivity α_{xy} were calculated based on the thermoelectromotive force V_{xy}. The transverse thermal conductivity α_{xy} is defined by the following formula (4).

α_{xy}=σ_{xy}Sₓₓ+σₓₓS_{xy} (4)
σ_{xy}: Hall conductivity
Sₓₓ: Seebeck coefficient
σₓₓ: electrical conductivity
S_{xy}: anomalous Nernst coefficient

Black circles in FIGS. 7 to 9 are graphs illustrating the calculation results. In each graph, a horizontal axis represents an Fe composition ratio, i.e., Fe/all constituent elements (an atomic ratio).

FIG. 7 is a graph illustrating a relationship between the Fe composition ratio and the anomalous Nernst coefficient. A vertical axis in the graph represents the anomalous Nernst coefficient (μV·K⁻¹). The anomalous Nernst coefficient is an index of performance of a thermoelectric conversion film that converts a temperature gradient into a thermoelectromotive force. In the graph in FIG. 7, the anomalous Nernst coefficient S_{xy} increases as the Fe composition ratio x increases. It can be seen that when the Fe composition ratio x is 0.74 or more, the anomalous Nernst coefficient exceeds 1.0 μV·K⁻¹, and thermoelectric properties are comparable to those reported for crystalline bulk Fe₃Sn (see Non Patent Literature 1). When the Fe composition ratio x is 0.87, the anomalous Nernst coefficient exhibits a maximum value of 2.00 μV·K⁻¹.

From the above results, currently, a large anomalous Nernst coefficient is generally considered to be 1.0 μV·K⁻¹ or more when expressing the performance of a thermoelectric conversion device. Therefore, it can be said that for a thermoelectric conversion device of an amorphous thin film having a composition formula FeₓSn₁₋ₓ, a sufficient effect can be expected when the range of x is 0.7≤x≤0.9.

For Fe alone, the anomalous Nernst coefficient is known to be −0.20 μV·K⁻¹ to −0.45 μV·K⁻¹ (J. Weischenberg et al., Phys. Rev. B 87, 060406 (R) (2013), W. Zhou and Y. Sakuraba, Appl. Phys. Express 13, 043001 (2020)), and the anomalous Nernst effect is recognized as an effect in an FeSn amorphous thin film.

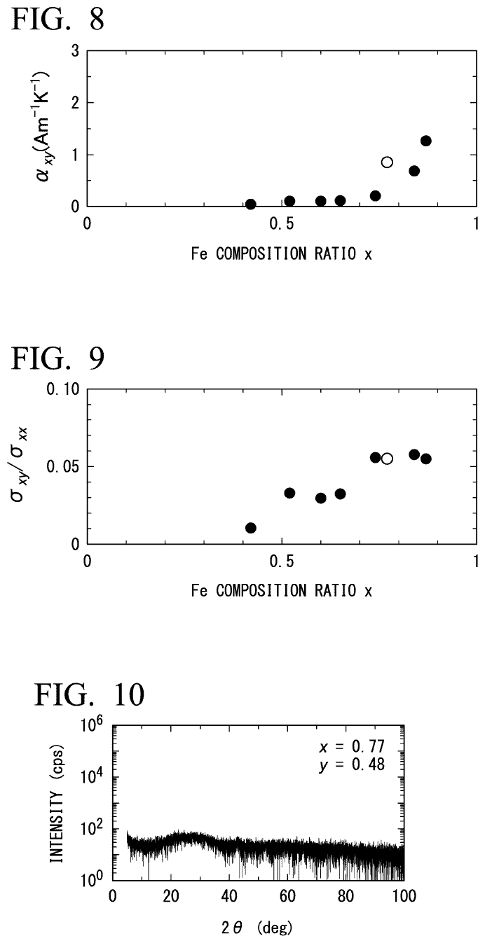

FIG. 8 is a graph illustrating a relationship between the Fe composition ratio and the transverse thermal conductivity. A vertical axis in the graph represents the transverse thermal conductivity α_{xy} (A/mK). The transverse thermal conductivity α_{xy} defined by the formula (4) is obtained by adding a component due to the anomalous Hall effect of carriers (electrons and holes) generated by the Seebeck effect (a first term) to a component due to the intrinsic anomalous Nernst effect (a second term). From the graph in FIG. 8, similar to the anomalous Nernst coefficient, the transverse thermal conductivity α_{xy} also tends to increase as the Fe composition ratio x increases.

FIG. 9 is a graph illustrating a relationship between the Fe composition ratio and the Hall angle. A vertical axis in the graph represents a tangent σ_{xy}/σₓₓ of the Hall angle. The tangent σ_{xy}/σₓₓ of the Hall angle indicates an index of strength of twisting of an electron orbital due to the Hall effect. From the graph in FIG. 9, it can be seen that the tangent σ_{xy}/σₓₓ of the Hall angle exhibits a broad peak near x=0.75 (0.6 to 0.75).

### Example 1-2

### [Composition Element Dependency]

In Example 1-2, in order to enhance the anomalous Nernst coefficient to improve properties of the thermoelectric conversion device, a sputtering method was used to obtain a thermoelectric conversion film composed only of an amorphous material even in the case of a thin film (thickness 43 nm) made of a composition containing aluminum (Al) as an impurity and represented by a composition formula Feₓ (Al_{y}Sn_{1-y})₁₋ₓ. Al is expected to modulate an electronic state near the Fermi level, which contributes to the anomalous Nernst effect, through modulation of spin-orbit interaction and carrier density. In X-ray diffraction illustrated in FIG. 10, no sharp peak derived from a crystal was observed in the thin film with x=0.77 and y=0.48.

A member made of indium was used as an electrode for detecting the anomalous Hall effect and the anomalous Nernst effect.

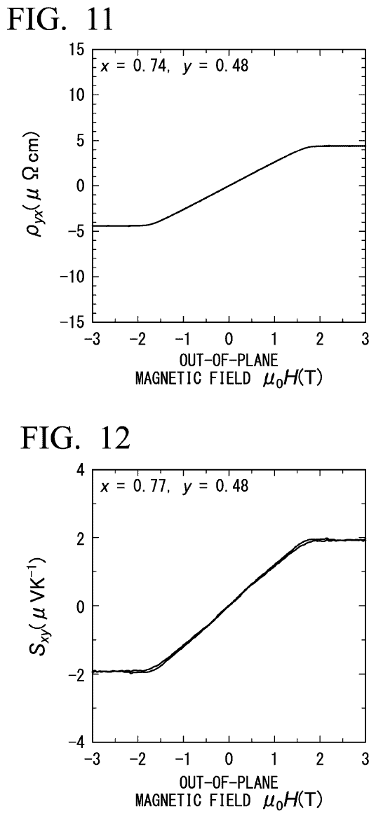

For one sample in which an Fe composition ratio x is 0.77 and an Al composition ratio y out of 0.23 occupied by Sn and Al is 0.48, a Hall voltage generated between electrodes due to the anomalous Hall effect of the thin film of the composition containing aluminum as an impurity in Example 1-2 was measured using a procedure same as that described in Example 1-1. FIG. 11 is a graph illustrating a result of the measurement.

The thermoelectromotive force V_{xy} generated between the electrodes due to the anomalous Nernst effect of the thin film having the composition containing aluminum as an impurity in Example 1-2 was measured using a procedure same as that described in Example 1-1. FIG. 12 is a graph illustrating a result of the measurement.

For comparison, results for the thin film having the composition containing aluminum as an impurity in Example 1-2 are illustrated as white circles respectively superimposed on the graph in FIG. 7 illustrating the relationship between the Fe composition ratio and the anomalous Nernst coefficient, the graph in FIG. 8 illustrating the relationship between the Fe composition ratio and the transverse thermal conductivity, and the graph in FIG. 9 illustrating the relationship between the Fe composition ratio and the Hall angle for the thin film made of Fe and Sn in Example 1-1.

Compared with the thermoelectric conversion film with the same Fe composition ratio of x=0.74 used in Example 1-1, the thermoelectric conversion film with x=0.77 and y=0.48 in Example 1-2 illustrates a high anomalous Nernst coefficient and a high transverse thermal conductivity. From this result, it was found that by adding aluminum to the same Fe composition ratio, the electronic state near the Fermi level, which contributes to the anomalous Nernst effect, is modulated, and the anomalous Nernst coefficient, which is an index of the performance of the thermoelectric conversion film, can be enhanced.

As described above, the amorphous thin film made of Fe and Sn of the invention may greatly improve the properties of the thermoelectric conversion device by adding, as an impurity, a transition element which has a potential to enhance the electromotive force due to the anomalous Nernst effect through the modulation of the magnetic interaction and the spin-orbit interaction, and a typical element which has a potential to enhance the electromotive force due to the anomalous Nernst effect through the modulation of the carrier density and the spin-orbit interaction, particularly, an element selected from a non-magnetic element such as aluminum and indium.

Other elements will be shown in experiments below.

### Example 2-1: Thermoelectric Conversion Device of Invention Using Amorphous Thermoelectric Conversion Film Containing Microcrystals

### [Composition Dependency]

In Example 2-1, properties when an amorphous thermoelectric conversion film containing microcrystals was used were examined.

A plurality of samples of the amorphous thermoelectric conversion film containing microcrystals were manufactured, and thermoelectric properties thereof were measured. In consideration of various applications of the thermoelectric conversion device, a sapphire Al₂O₃ substrate, which is a general-purpose substrate, was used. Using a sputtering method, a thin film (thickness 32 nm to 53 nm) made of a composition represented by a composition formula FeₓSn₁₋ₓ could be formed on the Al₂O₃ substrate as the amorphous thermoelectric conversion film containing microcrystals. From observations using a transmission microscope, a proportion of microcrystals was estimated to be approximately 5% to 50% of a total. The proportion of microcrystals tended to increase as an Fe composition ratio increased. A member made of indium was used as an electrode for detecting the anomalous Hall effect and the anomalous Nernst effect.

For seven samples in which the Fe composition ratio x was 0.44, 0.51, 0.60, 0.65, 0.73, 0.84, and 0.87, a magnetic field (a surface-perpendicular applied magnetic field) was applied in a thickness direction of the thermoelectric conversion film, and temperatures on one end side and the other end side in a direction orthogonal to the magnetic field were set to 300 K using the first temperature applying unit and the second temperature applying unit, respectively. Here, when a current was caused to flow from one end side (a first temperature applying unit side) to the other end side (a second temperature applying unit side) of the thermoelectric conversion film, a Hall voltage generated between the electrodes due to the anomalous Hall effect was measured.

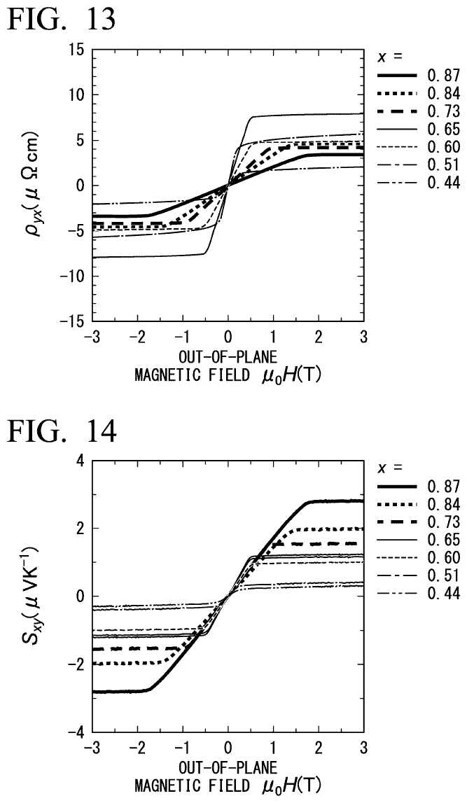

FIG. 13 is a graph illustrating a result of the measurement. A horizontal axis in the graph represents a surface-perpendicular applied magnetic field (T), and a vertical axis in the graph represents Hall resistivity ρ_{yx} [μΩ·cm]. From this graph, it can be seen that a change in magnetization direction caused by application of a magnetic field is reflected in the Hall resistivity.

In the seven samples, the magnetic field was applied in the thickness (out-of-plane) direction of the thermoelectric conversion film, and the temperature on one end side was maintained at about 300 K by the first temperature applying unit and the temperature on the other end side was adjusted to about 306 K by the second temperature applying unit in the direction orthogonal to the magnetic field without applying a current. As the first temperature applying unit, a sample holder of a refrigerator (VersaLab manufactured by Quantum Design) was used as a heat bath, and as the second temperature applying unit, heating by applying an electric current to a resistor was used. At this time, a thermoelectromotive force generated between the electrodes due to the anomalous Nernst effect was measured. A temperature gradient occurring in the sample was estimated from a calibration curve of a relationship between an applied current and a temperature difference, which was evaluated separately using an Al₂O₃ substrate equipped with a resistance thermometer. A temperature gradient of 0.937 K·mm⁻¹ estimated from the calibration curve was used.

FIG. 14 is a graph illustrating a result of the measurement. A horizontal axis in the graph represents the surface-perpendicular applied magnetic field (T), and a vertical axis in the graph represents an anomalous Nernst coefficient S_{xy} [μV·K⁻¹]. It can be seen from the graph that a change in magnetization direction caused by application of the magnetic field is reflected in the anomalous Nernst coefficient. It can be seen that, depending on the Fe composition ratio, a large anomalous Nernst coefficient occurs at a certain composition ratio.

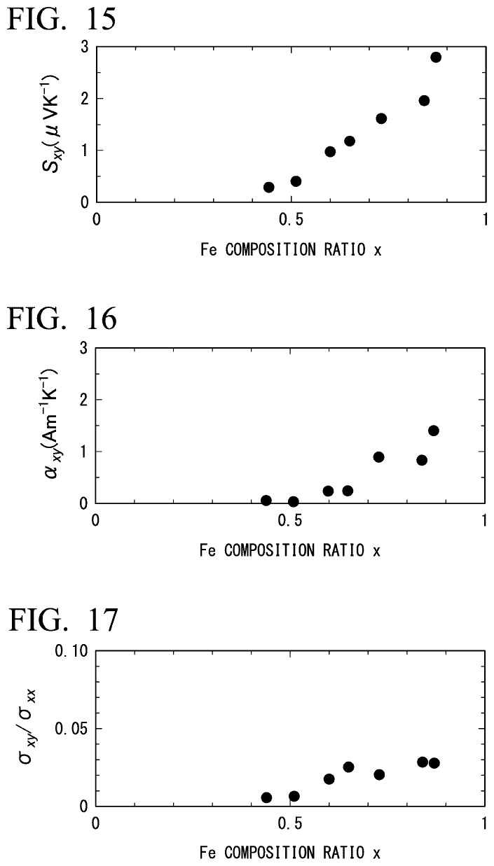

For all the samples manufactured as Example 2-1, the anomalous Hall effect was measured using a procedure same as that described in Example 1-1, and the Hall angle σ_{xy}/σₓₓ was calculated based on the Hall resistivity ρ_{yx} and the electrical resistivity ρₓₓ. The anomalous Nernst effect was measured using a procedure same as that described in Example 1-1, and the anomalous Nernst coefficient S_{xy} and the transverse thermal conductivity α_{xy} were calculated based on the thermoelectromotive force V_{xy}. FIGS. 15 to 17 are graphs illustrating the calculation results. In each graph, a horizontal axis represents an Fe composition ratio, i.e., Fe/all constituent elements (an atomic ratio).

FIG. 15 is a graph illustrating a relationship between the Fe composition ratio and the anomalous Nernst coefficient. A vertical axis in the graph represents the anomalous Nernst coefficient (μV·K⁻¹). In the graph in FIG. 15, the anomalous Nernst coefficient S_{xy} increases as the Fe composition ratio x increases. It can be seen that when the Fe composition ratio x is 0.6 or more, the anomalous Nernst coefficient exceeds 1.0 μV·K⁻¹, and thermoelectric properties are comparable to those reported for crystalline bulk Fe₃Sn (citing Sci. Adv. as a Non Patent Literature). When the Fe composition ratio x is 0.87, the anomalous Nernst coefficient exhibits a maximum value of 2.80 μV·K⁻¹.

FIG. 16 is a graph illustrating a relationship between the Fe composition ratio and the transverse thermal conductivity. A vertical axis in the graph represents the transverse thermal conductivity α_{xy} (A/mK). From the graph, similar to the anomalous Nernst coefficient, the transverse thermal conductivity α_{xy} also tends to increase as the Fe composition ratio x increases.

FIG. 17 is a graph illustrating a relationship between the Fe composition ratio and the Hall angle. It can be seen from the graph that a tangent σ_{xy}/Ox of the Hall angle exhibits a peak near x=0.85 in addition to near x=0.70.

### Example 2-2

### [Film Thickness Dependency]

Three samples of the thermoelectric conversion device of the invention were manufactured, and thermoelectric properties thereof were measured. Fe composition ratios x in the three samples were 0.60, 0.60, and 0.60, and thicknesses t of the thermoelectric conversion films were 20 nm, 40 nm, and 100 nm. Other configurations were the same as those in Example 2-1.

In the three samples, the thermoelectromotive force V_{xy} generated between electrodes due to the anomalous Nernst effect was measured using a procedure same as that described in Example 1-1. The thermoelectric coefficient S_{xy} was calculated using the measurement result. The calculation result is illustrated in Table 1. It can be seen that the anomalous Nernst coefficient S_{xy} is substantially constant, regardless of the thickness t of the thermoelectric conversion film.

TABLE 1

| x | t (nm) | S_{xy} (μV/K) |
|---|---|---|
| 0.60 | 20 | 0.982 |
| 0.60 | 40 | 0.869 |
| 0.60 | 100 | 1.14 |

### [Observation of Film Image]

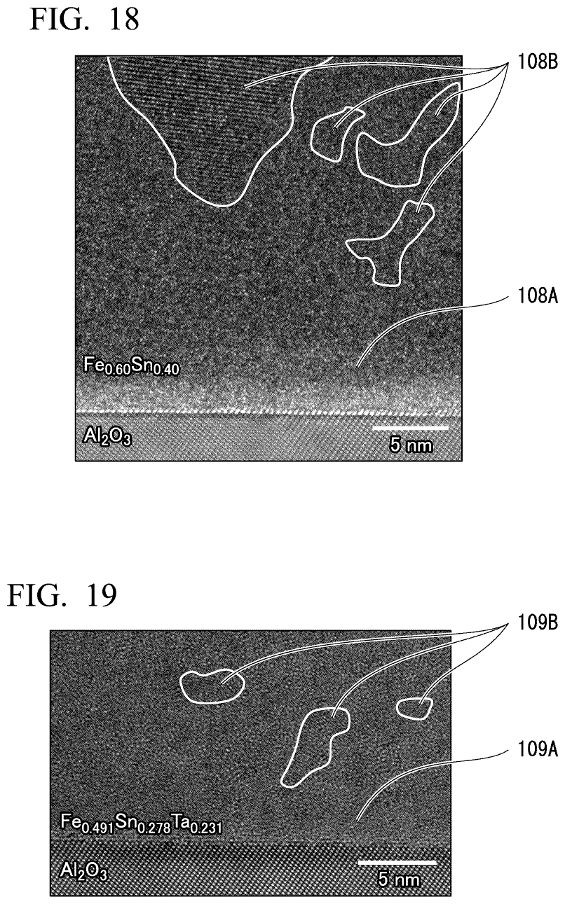

Of the thermoelectric conversion devices in Example 2-2, one in which the thermoelectric conversion film was made of a composition represented by a composition formula Fe_{0.60}Sn_{0.40} and was formed on an Al₂O₃ substrate was selected, and a surface of the thermoelectric conversion film was observed using a transmission electron microscope. FIG. 18 is an enlarged image of a portion of the observed surface. It can be seen that crystalline portions 108B are scattered throughout the thermoelectric conversion film, which mainly has an amorphous structure 108A.

### Example 2-3

### [Composition Element Dependency]

A plurality of samples of the thermoelectric conversion device of the invention were manufactured, and thermoelectric properties thereof were measured. An Al₂O₃ substrate was used as a substrate. A thin film made of a composition containing three elements was used as the thermoelectric conversion film. A composition formula of the composition was Fe_{0.415}Ta_{0.218} Sn_{0.367}, Fe_{0.511}Ta_{0.217}Sn_{0.272}, Fe_{0.717}In_{0.034}Sn_{0.349}/Fe_{0.697}Al_{0.098}Sn_{0.205}, and Fe_{0.768}Al_{0.112}Sn_{0.120}.

A member made of indium was used as an electrode. The thermoelectromotive force V_{xy} generated between electrodes due to the anomalous Nernst effect was measured, and the measurement result was used to calculate the anomalous Nernst coefficient S_{xy}. The calculation result is illustrated in Table 2.

TABLE 2

| | | | | | Thickness | Anomalous |
|---|---|---|---|---|---|---|
| | | | | | (nm) of | Nernst |
| Composition ratio | | | | | thermoelectric | coefficient |
| Fe | Sn | Ta | In | Al | conversion film | Sxy (μV · K⁻¹) |
| 0.415 | 0.367 | 0.218 | — | — | 58 | 0.90 |
| 0.511 | 0.272 | 0.217 | — | — | 50 | 1.22 |
| 0.717 | 0.349 | — | 0.034 | — | 39 | 1.33 |
| 0.697 | 0.205 | — | — | 0.098 | 48 | 2.40 |
| 0.768 | 0.120 | — | — | 0.112 | 47 | 2.80 |

The graph in FIG. 15 and the measurement result in Table 2 can be compared as follows based on the Fe composition ratio.

The anomalous Nernst coefficient S_{xy} when the Fe composition ratio is about 0.415 is about 0.25 in the case of an Fe—Sn composition (FIG. 15), whereas the anomalous Nernst coefficient S_{xy} is 0.90 in the case of an Fe—Sn—Ta composition (Table 2).

The anomalous Nernst coefficient S_{xy} when the Fe composition ratio is about 0.511 is about 0.4 in the case of the Fe—Sn composition (FIG. 15), whereas the anomalous Nernst coefficient S_{xy} is 1.22 in the case of the Fe—Sn—Ta composition.

The anomalous Nernst coefficient S_{xy} when the Fe composition ratio is about 0.717 is about 1.5 in the case of the Fe—Sn composition (FIG. 15), whereas the anomalous Nernst coefficient S_{xy} is 1.33 in the case of an Fe—Sn—In composition (Table 2).

The anomalous Nernst coefficient S_{xy} when the Fe composition ratio is about 0.697 is about 1.4 in the case of the Fe—Sn composition (FIG. 6), whereas the anomalous Nernst coefficient S_{xy} is 2.40 in the case of an Fe—Sn—Al composition (Table 2).

The anomalous Nernst S_{xy} when the Fe composition ratio is about 0.768 is about 1.8 in the case of the Fe—Sn composition (FIG. 15), whereas the anomalous Nernst coefficient S_{xy} is 2.80 in the case of the Fe—Sn—Al composition (Table 2).

From these comparisons, it can be seen that when the Fe—Sn composition is doped with Ta and/or Al, the anomalous Nernst coefficient can be significantly increased. In particular, Al has a significant increase in anomalous Nernst coefficient. It is considered that this result is because, as described above, the electronic state near the Fermi level, which contributes to the anomalous Nernst effect, is modulated, and the anomalous Nernst coefficient, which is an index of the performance of the thermoelectric conversion film, can be enhanced.

In order to improve properties of a magnetic material containing a transition element as a main component, other transition elements are often added as impurities in order to modulate the magnetic interaction, and in the invention, a great effect is achieved by using Al, a typical element that is less expensive than Ta, a transition element. Therefore, the Fe—Sn composition of the invention is an inexpensive material and is likely to achieve a significant increase in anomalous Nernst coefficient.

As described above, even when the amorphous thin film made of FeSn of the invention contains microcrystalline particles, the properties of the thermoelectric conversion device may be greatly improved by adding, as an impurity, an element selected from a transition element having a potential to enhance the electromotive force due to the anomalous Nernst effect through the modulation of the magnetic interaction and the spin-orbit interaction, a typical element having a potential to enhance the electromotive force due to the anomalous Nernst effect through the modulation of the carrier density and the spin-orbit interaction, and the like.

### [Observation of Film Image]

Of the thermoelectric conversion devices in Example 2-3, one in which the thermoelectric conversion film was made of a composition represented by the composition formula Fe_{0.491}Sn_{0.278} Ta_{0.231} was selected, and a surface of the thermoelectric conversion film was observed using a transmission electron microscope. FIG. 19 is an enlarged image of a portion of the observed surface. It can be seen that crystalline portions 109B are scattered throughout the thermoelectric conversion film, which mainly has an amorphous structure 109A.

### Effects, Etc

According to Examples of the invention, a large thermoelectromotive force was observed in a thin film having a substantially amorphous structure composed of Fe and Sn. In related art, it has been reported that a thermoelectric conversion film is obtained by dispersing a metal or the like in a crystalline bulk, a thin film, or a polymer, but in the invention, a high-performance thermoelectric conversion film can be obtained by a magnetic thin film having only an amorphous structure. In particular, in the amorphous thin film represented by the composition formula FeₓSn₁₋ₓ, where 0.7≤x≤0.9, a large value exceeding 1.0 μV·K⁻¹ could be obtained as the anomalous Nernst coefficient (one of performance indices of the thermoelectric conversion device based on the anomalous Nernst effect).

Accordingly, a thermoelectric conversion device that has excellent thermoelectric properties and flexibility, has a small environmental load, can be manufactured at room temperature, and can be miniaturized as an element can be provided.

Since there is no significant change in performance even when microcrystals are contained, versatility of manufacturing is high, and manufacturing can be performed at low cost.

Further, since the properties of the thermoelectric conversion device may be greatly improved by incorporating a transition element, a typical element, or the like as an additive, innovative improvement in performance can be expected depending on the composition. In particular, by incorporating an inexpensive typical element such as Al, improvement in performance can be expected, and an inexpensive and high-performance thermoelectric conversion device can be provided.

### INDUSTRIAL APPLICABILITY

The invention can provide a thermoelectric conversion device that has excellent thermoelectric properties and flexibility, has a small environmental load, and can be manufactured at room temperature.

### REFERENCE SIGNS LIST

100, 110, 120 thermoelectric conversion device
101 substrate
101a one surface of substrate
102 thermoelectric conversion film
103 first electrode
104 second electrode
105 first temperature applying unit
106 second temperature applying unit
107 wavy pattern
107a one end of wavy pattern
107b other end of wavy pattern
108A, 109A amorphous structure
108B, 109B crystal portion
E thermoelectromotive force
M magnetization
∇T temperature gradient

1. A thermoelectric conversion device comprising:
a substrate;
a thermoelectric conversion film formed on one surface of the substrate;
a first temperature applying unit configured to apply a temperature to the thermoelectric conversion film on a substrate side; and
a second temperature applying unit configured to apply a temperature to the thermoelectric conversion film on a side opposite to the substrate side, the temperature being different from the temperature on the substrate side, wherein
the thermoelectric conversion film has an amorphous structure made of a composition containing Feₓ and Sn₁₋ₓ (0.4≤x≤0.9).

2. The thermoelectric conversion device according to claim 1, wherein
the amorphous structure accounts for 50% or more of a total volume of the thermoelectric conversion film.

3. The thermoelectric conversion device according to claim 2, wherein
the thermoelectric conversion film has a plurality of portions having a crystal structure, and a total volume of the portions is 5% or more and 50% or less of the total volume.

4. The thermoelectric conversion device according to claim 1, wherein
the composition is represented by a composition formula FeₓSn₁₋ₓ, where 0.7≤x≤0.9.

5. The thermoelectric conversion device according to claim 1, wherein
the amorphous structure has a ratio of a peak value associated with Bragg reflection to noise of 30 or less in an X-ray diffraction pattern.

6. The thermoelectric conversion device according to claim 1, wherein
the composition further contains an element A selected from Ta, W, Pt, Mo, Mn, In, Al, Ge, Si, and Ga, and is represented by a composition formula Fe_{x-y}Sn_{1-x-z}A_{y+z}, where 0.4≤x≤0.9, 0.05≤y≤0.6, and 0.05≤z≤0.4.

7. The thermoelectric conversion device according to claim 1, wherein
the composition further contains an element B selected from a typical element other than Sn, and is represented by a composition formula Fe_{x-y}Sn_{1-x-z}B_{y+z}, where 0.4≤x≤0.9, 0.05≤y≤0.6, and 0.05≤z≤0.4.
